(19) United States
(12) Patent Application Publication
(10) Pub. No.: US 2009/0183983 A1
(43) Pub. Date: Jul. 23, 2009

(54) INSERT PIECE FOR AN END-BLOCK OF A SPUTTERING INSTALLATION

(75) Inventors: Ivan Van De Putte, Roeselare (BE); Wilmert De Bosscher, Drongen (BE)

Correspondence Address: FOLEY AND LARDNER LLP;SUITE 500, 3000 K STREET NW, WASHINGTON, DC, 20007, US

(73) Assignee: Bekaert Advanced Coatings

(21) Appl. No.: 12/304,213

(22) PCT Filed: Jun. 13, 2007
(86) PCT No.: PCT/EP07/55791

§ 371 Date: Dec. 10, 2008

(30) Foreign Application Priority Data
Jun. 19, 2006 (EP) 06115659.2

(51) Int. Cl. H01J 37/34

(52) U.S. Cl. 204/192.12; 204/298.16

(57) ABSTRACT

An insert piece (340) is described for introducing between the mounting base (314) and the end-block (310) of a magnetron sputtering installation. Such an insert piece replicates (320′, 322′) on one end the end-block interface (322) and at the other end the mounting base interface (320). Inside the insert, transfer rods (342) and tubing (444,444′) are provided for the transfer of coolant, electrical current and motive force between the mounting base (314) and the end-block (310). The insert piece (340) is useful to adjust the distance between the target and the substrate. An advantageous embodiment of the insert piece incorporates resilient means into it for accommodating small movements of the end-block caused by thermal expansion or sagging of the target tube. In another advantageous embodiment, the inserts are so long that they cross the plane of the substrate. In this way a target can conveniently be mounted to coat the side opposite to the normal coating side of the substrate without the need for extensive refurbishment of the installation.

### FIELD OF THE INVENTION

The invention relates to an accessory—an insert piece—to adjust the distance between a sputtering target and a substrate in a sputtering installation. By introducing the inventive insert piece, this distance can be conveniently adjusted, without further changes to the installation.

### BACKGROUND OF THE INVENTION

Sputtering has become an established coating technique to coat planar substrates such as display glass sheets, window panes, touch screens and many other contemporary appliances. In a sputtering apparatus the substrates to be coated are conveyed in front of a sputtering magnetron. Such a sputtering magnetron acts as an atomic spray source, whereby target material atoms—with which one wants to coat the substrate—are dislodged from the target surface by ions electrically accelerated out of a low pressure gaseous plasma. The plasma is confined by a magnetic field sustained by magnets mounted oppositely to the sputtering side of the target. In this sputtering process, the distance between the target and the substrate is important for various reasons that will now be touched upon:

Although the spraying of atoms mainly occurs in a direction perpendicular to the target surface, there is quite some angular spread due to the stochastic nature of the dislodgement process. In order to guarantee the uniformity of the coating, it is therefore advisable to have the target extending over the edge of the substrate at least twice the target-to-substrate distance. Larger target-to-substrate distances therefore lead to an increased spill-over at the edges. An increased spill-over automatically also implies a lower overall coating speed. Additionally, a larger target-to-substrate distance implies a higher probability for a collision with gas atoms of a dislodged target atom on its way to the substrate, again leading to a lower coating efficiency. Sometimes there is a need for having the magnetic field lines extend up to the substrate to fine-tune the properties of the coating. When this is necessary, special magnet arrays are used that yield a further extending magnetic field. As the strength of a magnetic field steeply drops off with the distance—it is a dipole field—the possibilities of such so-called ‘unbalanced magnetrons’ to extend the magnetic field lines are rather limited in distance. In that case it may be helpful to move the magnetron in its entirety closer to the substrate, so that the coated substrate comes under influence of the magnetic field lines.

The target-to-substrate distance also influences the temperature of the substrate: as the target tends to become quite hot (and therefore has to be cooled) due to the impact of the gas ions, the heat radiation will heat up the substrate. Sometimes, this can be helpful in the process e.g. to improve adhesion or secondary reactions in the coating, but it can also be detrimental for the substrate for example when the substrate has a low softening point. In that case it can be necessary to increase the distance.

Likewise, it can be interesting to increase the target-to-substrate distance in order to limit the impact of arcing at the target substrate. Arcs—sparks that occur on the target surface between sputtered and non-sputtered regions—may impart enough energy to eject larger pieces of target material towards the substrate. When this occurs too close to the substrate, this can lead to defects in the coating.

A need to be able to adjust the target-to-substrate distance has therefore always existed in sputtering apparatus. While for stationary, planar coaters—such as used in the electronics industry to coat wafers with a diameter of 200 or 300 mm—the adjustment of the target-to-substrate distance is relatively straightforward, it is much more difficult in the case of rotating, tubular targets extending over 4 meters width in large area coaters.

The idea of having the target material fed into the plasma by providing the target material in the form of a rotating tubulus in which a stationary, elongated magnetic field is maintained at the surface of it, was first described in a series of U.S. Pat. Nos. (4,356,073, 4,422,916, 4,443,318, 4,445,997, 4,466,877) attributed to McKelvey. The advantages of having a larger stock of material, a better cooling and better process control outweighed the disadvantages of a target mounting with increased complexity. Indeed, a high electrical current has to be fed to the target to sustain the plasma, that on its turn makes it necessary to cool the target by means of a coolant circulating in and out of it, while it is being rotated in front of a magnetic array that has to be kept stationary and this all while maintaining vacuum integrity.

Basically two competing designs have emerged out of this basic idea.

Firstly, there is the solution of feeding the target tube's necessities of coolant in, coolant out, electrical current and motive force from a single bearing house called ‘end-block’ mounted on the wall of the vacuum chamber. In this case the target axis is generally perpendicular to the wall to which the end-block is mounted. This is known as the cantilever mount (U.S. Pat. No. 4,549,885, U.S. Pat. No. 4,519,885, U.S. Pat. No. 5,200,049, US 2004/0140208, WO 2006/023257). A small mechanical support at the target end opposite to the end-block may be necessary to provide mechanical support during operation. By providing elongated slots for the mounting screws of the end-block to the wall, the target-to-substrate distance can relatively easily be adjusted.

Secondly, there is the solution of distributing the necessities for the target over two end-blocks situated at either end of the target. In this case the target is mounted with its axis parallel to the wall on which the end-blocks are mounted. The end-blocks are then of the ‘right-angled’ type. Examples of further developments are described in U.S. Pat. No. 4,422,916, U.S. Pat. No. 4,445,9975, U.S. Pat. No. 5,096,562, U.S. Pat. No. 6,736,948, WO 2006/007504. Within this second solution, two ‘design schools’ have emerged, one wherein the end-blocks are boxes that are attached to the wall wherein the interior of the box remains reachable and visible from the atmospheric side of the wall (as e.g. in U.S. Pat. No. 6,736,948), the second wherein the end-blocks are closed modular boxes provided with an interface that matches with an interface on a base incorporated in an installation wall whereby the interface allows quick (dis)mounting with a single locking screw as shown on

http://www.bekaert.com/bac/Products/Sputter%20hardware/End%20Block.htm.

FIGS. 1a and 1b provides a simplified drawing of the latter design, wherein an end block 110 for carrying a rotatable target 112 is removably attachable to a mounting base 114 that is provided in the wall 116 of a sputtering apparatus. The mounting base 114 has a base interface 120 that matches with an end-block interface 122. The interfaces 120, 122 are pressed against one another by means of a screw ring 118. Through the interfaces 120, 122 coolant or electrical current or motive force is transferred from the supply lines 122, 122′ to the target 112. When in this existing design an adaptation needs to be made in order to move the rotatable target further away from the mounting base i.e. closer to the substrate, an opening is cut in the wall of the sputtering installation. As shown in FIGS. 2a and 2b this can be done by cutting an opening in the wall 216 of the sputtering installation and welding or bolting with static seals (e.g. O-rings) a box 230 to it. On the bottom of box 230, a mounting base 214 is mounted. Needless to say that such a procedure presents a lengthy, profound change to the sputtering installation. In addition, all supply lines need to be extended and connecting them within this box is not straightforward. The inventors therefore sought and found a solution to this problem.

### SUMMARY OF THE INVENTION

The object of the invention therefore to provide a quick, reversible and easy system by which the spatial position of the end-block in the sputtering installation can be changed. An accessory is introduced that provides the possibility to change the distance between the mounting base and the end-block within minutes in case end-blocks are of the closed, modular type. Besides the problem of end-block positioning, some other problems can be solved as a bonus as will be described below.

According a first aspect of the invention, an insert piece with the features of claim 1 is presented. The insert piece can be inserted between the mounting base that is available inside the sputtering installation and an end-block. Such mounting base/end-block combinations are known in the art. Commonly one or more (usually an even number) of mounting bases are available on sputtering modules that are mountable onto sputtering installations. Such mounting base generally comprises a collar that is fixed to the flange of the sputtering module that is the flange that interfaces vacuum-tight to the sputtering installation. The mounting base has a base interface that matches to the end-block interface of the end-block. By matching these interfaces with one another the necessities of coolant feed or coolant extraction or electrical current feed or motive force needed for operating a rotatable target are automatically interconnected when base and end-block are clamped against one another. Moreover, the interfaces provide for means to prevent possible leaks of coolant and/or gas such as O-rings and O-ring receiving recesses. To the end-block itself the target tube is connected by means of a rotatable interconnect. A number of interconnects are known in the art such as described in U.S. Pat. No. 5,591,314 and WO 00/00766. The function of the end-block is to transfer the sputtering necessities to the target while allowing rotation in vacuum. To this end rotatable vacuum seals, rotatable coolant seals, a rotatable current connector, bearings for carrying the target and retention means to keep the magnetbar in place are provided inside the end-block. The end-blocks as described could be straight through end-blocks or they can be end-blocks of the right-angled type.

Characteristic of the inventive insert piece is now that one end of it is provided with a replica of the base interface while the other end is provided with a replica of the end-block interface. When inserted, the base interface replica of the insert is connected to the interface of the end-block and the end-block interface replica of the insert is connected to the base interface. It is as if the mounting base is displaced into the sputtering installation and therefore the end-block can be situated elsewhere inside the vacuum chamber. As the function of the insert is not only merely to displace the end-block but also to maintain its operability, means must be provided inside the insert to achieve this.

The freedom for moving into the vacuum chamber is practically unlimited, but consideration has to be given to the fact that the inserts must be able to carry the weight of the end-blocks together with the target and the coolant. Therefore two configurations are particularly favoured namely the one wherein the interfaces are in planes that are substantially parallel to one another and the one wherein the interfaces are in planes that are substantially perpendicular to one another.

How the interfaces are clamped against one another is particularly important as this clamping must be able to carry the load of the end-block with target and coolant. A first way to realise this is to have a screw ring connection. A threaded ring is then rotatably held on the insert at the base interface replica end by means of a circumferential ridge on the insert that abuts with an inside step at the one ring end. At the inside towards the other end of the ring, an inner thread is cut out that engages with the outer thread of the end-block. Firstly the interfaces of end-block and insert are carefully matched to one another and then the screw ring is threaded on and tightened with a spanner wrench. At the other end of the insert, the screw ring is retained by the mounting base, while the outside threading is on the end of the insert with the end-block interface replica. Another way to secure the insert to the mounting base and the insert to the end-block is to use a segmented straining ring. Such a ring has a V-type slit cut out on the inside and is segmented usually in two or three segments that are hingably connected to one another. The slit catches the frustoconical flanges on both the end-block and the insert and the insert and the mounting base. The interfaces are tightly pressed against one another when a spanner screw connecting two segments is closed (much alike an ISO-KF type of vacuum connector).

In order to properly connect the interfaces to one another, it is beneficial to provide a guiding pin fitting into a hole in order to obtain a good alignment. As an alternative, the feedthrough of the electric current or the in or outlet of the coolant can be used to provide guidance for the mating interfaces.

Other types of couplings can of course also be used such as e.g. bayonet type of couplings.

In order to maintain the operability of target when an insert is introduced between the mounting base and the end-block, the necessities that have to be fed to the target have to be transferred through the insert. As mentioned before: to keep the target functioning, the following is needed:
supply of a negative electrical current for maintaining the plasma and accelerating the positive ions in the plasma towards the target in order to displace sputter material atoms out of the target. The kinetic impact of the ions is high and most of the energy supply is therefore transformed into heat i.e. the target gets hot. Transfer through the insert piece of the current can be achieved through a solid copper bar axially resiliently mounted in the insert piece.
therefore a coolant supply—usually chilled water—for keeping the target on a working temperature is needed. As quite some cooling power is needed, the heated coolant has to be extracted out of the target. A closed cooling circuit is used to this end. At the mounting base interface replica of the insert tube snouts are present engaging with the receiving mouth of the end-block while at the other end the end-block interface replica mouths receive the snouts of the mounting base.
in order to feed new target material into the plasma motive force has to be supplied to the target to keep it rotating. Rotation of the target is also important because the heated part of the target is cooled down once it exits the plasma region. Rotation is normally achieved by a shaft with a rotary restrained socket and pin arrangement although other types of rotation transfer are equally possible. In the insert, the motive force can be transmitted through a solid shaft held by bearings and foreseen with the appropriate socket and pin arrangements at either side. Also flexible shafts can be used to this end.

During operation the target will anyhow get warmer. This leads to axial expansion of the target. Besides that radial deviations of the target can also occur due to e.g. sagging of the target tube. In order to keep the sputtering process in control, theses deviations from the ideal case (no axial or radial deviations) must be kept to a minimum. However, this is not possible and the deviations may—in extreme cases—lead to excessive wear on seals and bearings in the end-block. In U.S. Pat. No. 6,736,948 a solution has been found to this problem by the introduction of an ‘axially compliant end-block’. The inventors realised that the same problem can easily be overcome by the use of their inserts when they have some resilience. The resilience must allow for small deviations of the interface replicas with respect to one another. Such resilience can be obtained in a number of ways:
the use of resilient O-rings between the interfaces. As currently such O-rings are present, there is already a minor degree of resilience. However, this can be improved by using e.g. thicker O-rings, O-rings with better resilience properties, double O-rings (one at each side of the interface)
the use of resilient housings for the insert. The housing—which will be normally tubular although other shapes are not excluded—could be made of a high-grade polymeric materials such as Flametec™, Kytec®PVDF (polyvinylidene fluoride) or ECTFE (a copolymer of ethylene and chlorotrifluoroethylene) or PEEK™ (Polyetheretherketone) that allows for some resilience. Alternatively a metal tube can be used whereto a circumferential metallic spring is welded such as e.g. a part of a stainless steel vacuum bellows.
   A combination of these features remains of course also possible. Care must be taken that the transfer means in the insert and at the interfaces are not overstrained and remain functioning when the insert is forced out of its equilibrium position. To this end hoses, flexible shaft and flexible electrical conductors can be used to transfer the necessities through the insert piece.

According a second aspect of the invention, a pair of insert pieces is claimed. From the above it will be clear that in case two end-blocks are used that support the two ends of the target, not all necessities to operate the target must be supplied by both end-blocks. Indeed the necessities can be divided over the two end-blocks. When ordering these necessities as (F) coolant feed, (E) coolant extraction, (C) electrical current feed, (M) motive force, 7 meaningfull divisions of the necessities can be made: [F][ECM], [E][FCM], [C][FEM], [M][FEC], [FE][CM], [FC][EM] and [FM][EC]. Although each of these divisions is technically equally implementable, the combination of [M][FEC] and [C][FEM] can be found in practice.

According a third aspect of the invention, a sputtering module is claimed. Such modules serve as carriers for the mounting base and usually contain all the necessary feed and control ancillaries of tubing and electronics. However, the module can also be a door to which a mounting base is fixed carrying an end-block on the inside (as e.g. described in pending application PCT/EP2006/060216). Between the end-block and the mounting base, the inventive insert is mounted. The design of the insert piece directly allows them to be mounted in series as the interfaces are compatible.

The modules can also be equipped with a pair of matching mounting base and end-block couples (i.e. the first member of such a pair comprises a first mounting base matchable to a first end-block and the second member of such a pair comprises a second mounting base matchable to a second end-block). Such a pair can carry one target. Likewise another pair of (mounting base, end-block) couples can be added to the same module to carry a second target. Modules exist that carry up to four targets but the principle can be extended even further. The inventive inserts can be advantageously used to lower one target relative to another. When the inserts are made even longer they can even extend under the plane of the substrate where a second target can be mounted that sputters the other side of the substrate in one single pass. In this way the ideas disclosed in application PCT/EP2006/063173 becomes particularly simple and easy to implement in practice!

By this invention, existing installations can be conveniently adapted by insertion of the above described insert pieces between the different (or one) mounting bases and corresponding end-blocks. Such an adaptation method can be executed quickly and conveniently—without any special tooling—as no extension of supply lines on the existing installation are necessary, nor is any special adaptation to the coating module needed.

### BRIEF DESCRIPTION OF THE DRAWINGS

The invention will now be described into more detail with reference to the accompanying drawings wherein

FIGS. 1a and 1b describe the standard situation of an end-block mounting.

FIGS. 2a and 2b show the prior art solution for lowering a target towards the substrate.

FIGS. 3a and 3b show a front and a cross section of how the insert piece can be beneficially used.

FIGS. 4a, 4b and 4c show a side view, an axial cross section and a cross section perpendicular to axis of an [FEC] type insert.

FIGS. 5a, 5b and 5c show a side view, an axial cross section and a cross section perpendicular to axis of an [M] type insert.

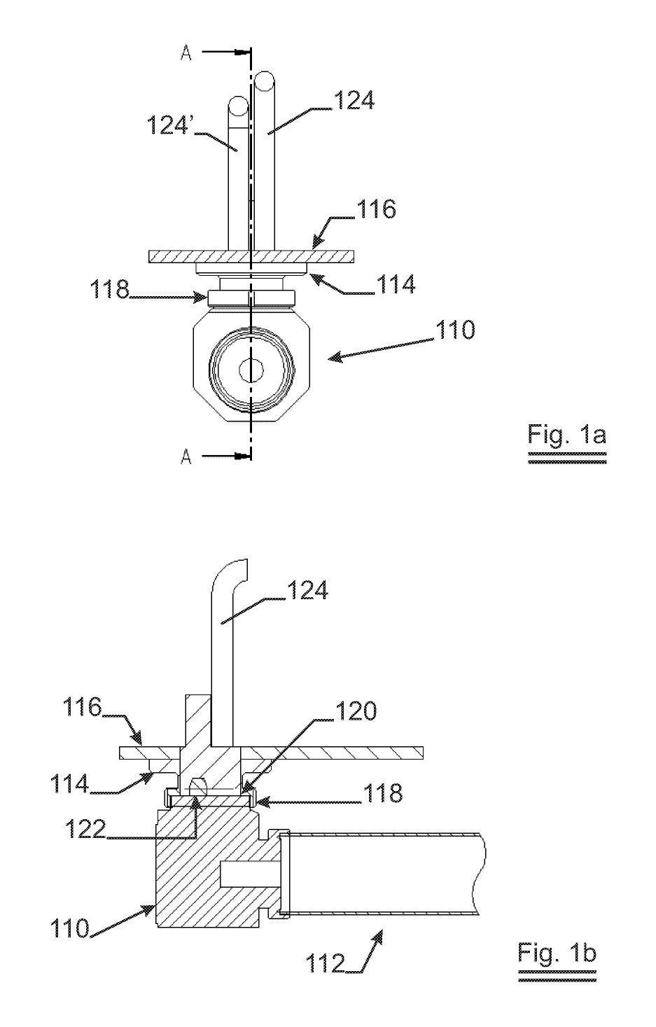

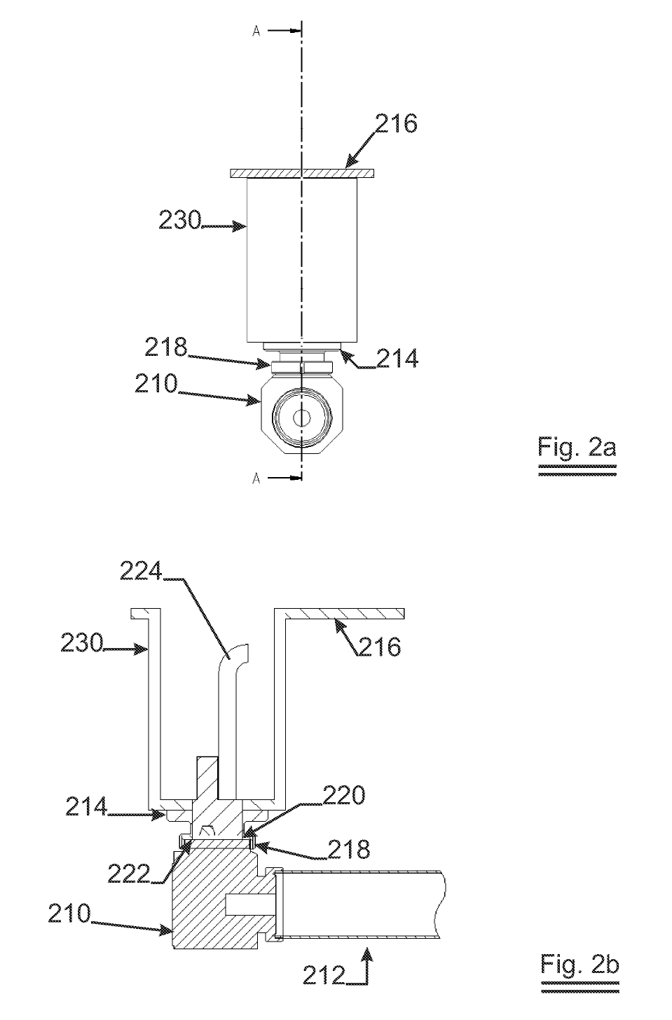

As the prior-art as depicted in FIG. 1a, 1b and FIG. 2a, 2b has been largely discussed in the ‘Background of the invention’ section, these figures will not be further explained in what follows. In the drawings like pieces are denominated with the last two digits of the denominators equal. The first digit then refers to number of the figure.

### DESCRIPTION OF THE PREFERRED EMBODIMENTS OF THE INVENTION

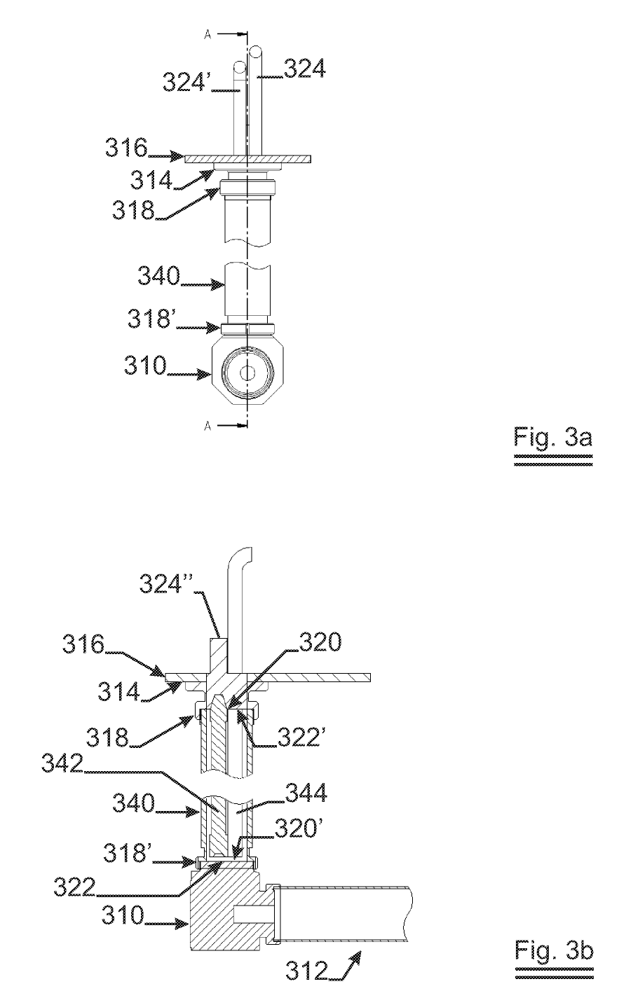

FIG. 3a, 3b show how the insert piece can be conveniently introduced in an existing installation without a need for adapting the installation. The existing components of the mounting base 314 that is fixed to the wall 316 of the coating apparatus are shown. The end-block 310 is matchable to the mounting base 314 through the interfaces 320 and 322 but in this case the insert piece 340 has been introduced between the mounting base and the end-block. The insert piece 340 has a replica 322′ of the end-block interface 322 and a replica 320′ of the mounting base interface 320. The screw ring 318 that previously was used to tighten the end-block to the mounting base is now used to fix the insert piece 340 to the mounting base 314. A copy of the screw ring 318′ is now introduced to tighten the end-block to the insert piece. Inside the insert piece 340 means 344, are provided to transfer the coolant from the supply and extract tubes 324, 324′ to the end-block and to transfer the current from connector 324′ to the end-block 310 via connector rod 342.

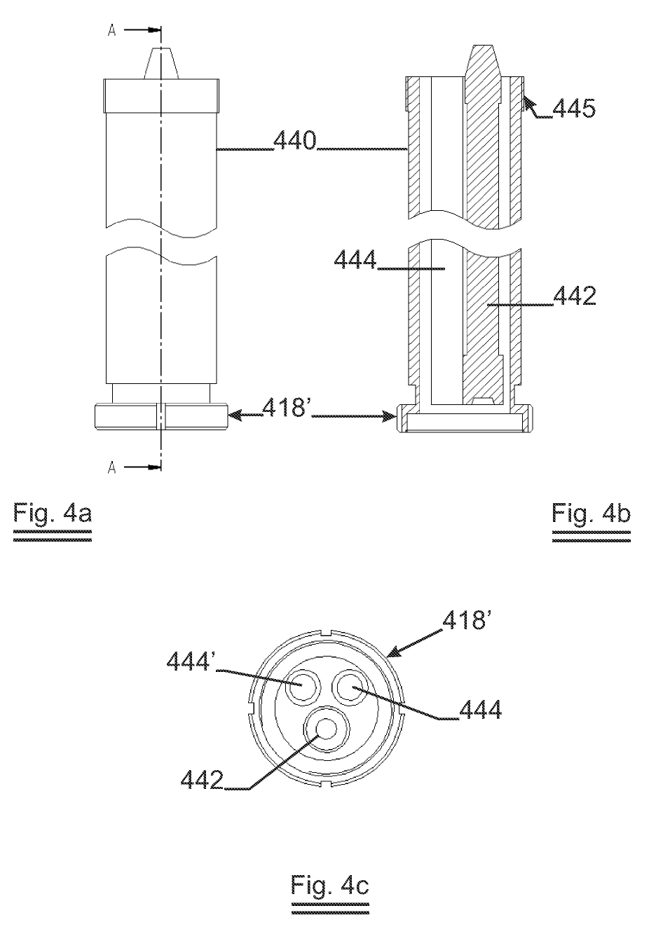

FIGS. 4a, 4b and 4c further shows the insert piece 440 of FIG. 3 in more detail. At the one end of the insert piece screw thread 445 is provided for threading with the screw ring of the mounting base. The connector rod 442 is axially movable mounted—possibly spring loaded—in the insert 442 to ensure proper electrical contact. Tubing 444, 444′ is provided with a spout and mouth connector (not shown) one for feeding coolant, one for extracting coolant from the end-block. Screw ring 418′ is a copy of the screw ring of the mounting base and screws onto the end-block thread.

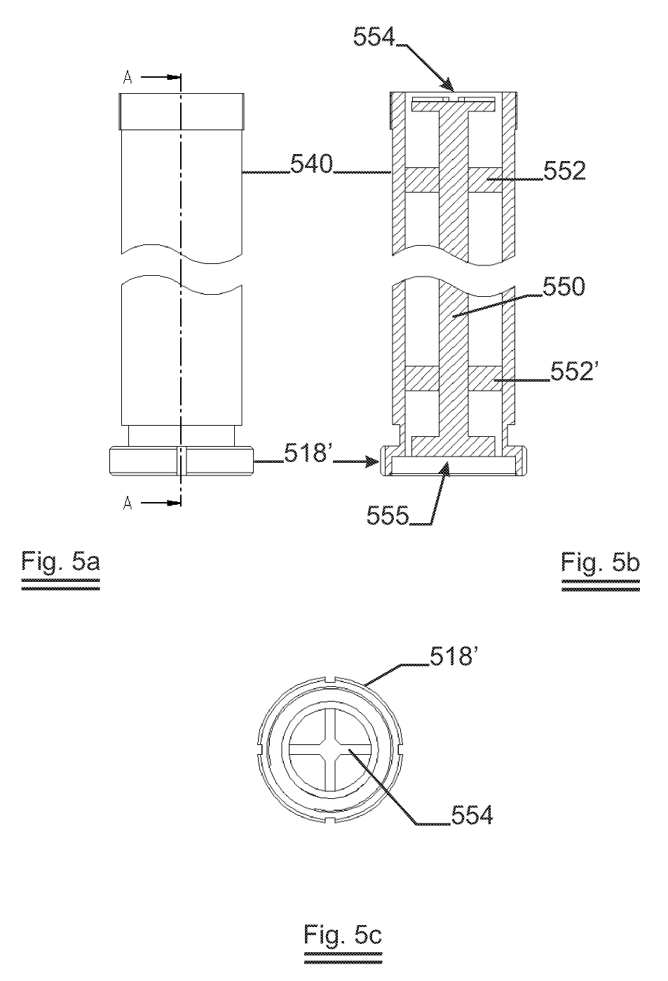

FIGS. 5a, 5b and 5c shows the other member of the pair of insert pieces that transfers motive force. The outer shell 540 of the insert piece remains identical. Inside a rotary shaft 550 is held by rotary bearings 552, 552′. Motive force is brought over from the mounting base through transfer disk 554 having a crosswise recess in which studs from the mounting base shaft engage. These studs are copied at the other end of the insert 555 for further connection to the end-block.

Both inserts are provided with the necessary vacuum and coolant seals in order to prevent leaks. These seals are stationary seals in the sense that the parts they seal to not move relative to one another. All rotary seals are incorporated inside the end-block. As a result, the pressure inside the insert piece can be held atmospheric.

1. An insert piece insertable between
a mounting base available inside a sputter coating installation and
an end-block removably attachable to said mounting base said end-block for carrying a rotatable sputter magnetron inside said sputter installation, said mounting base having a base interface matching with an end-block interface of said end-block
characterised in that
at the one end of said insert piece a base interface replica is provided and at the other end of said insert piece an end-block interface replica is provided, said piece further comprising means to operably connect said mounting base to said end-block thus providing an increased freedom for positioning said end-block inside said sputter coating installation.

2. The insert piece according to claim 1 wherein the rotatable sputter magnetron is an elongated, tubular magnetron.

3. The insert piece according to claim 1, wherein the end-block is a right-angled end-block.

4. The insert piece according to claim 1, wherein the plane of the base interface replica is substantially parallel to the plane of the end-block interface replica.

5. The insert piece according to claim 1, wherein the plane of the base interface replica is substantially perpendicular to the plane of the end-block interface.

6. The insert piece according to claim 1, wherein the matchable interfaces are securable to one another by means of a screw ring.

7. The insert piece according to claim 1, wherein the matchable interfaces are securable to one another by means of a segmented straining ring.

8. The insert piece according to claim 1, wherein the matchable interfaces are securable to one another by means of a bayonet coupling.

9. The insert piece according to claim 1, further comprising means to transfer coolant, electrical current and motive force between said mounting base and said end-block.

10. The insert piece according to claim 1, further comprising resilient means for allowing displacements out of the equilibrium position of said insert piece while remaining operative.

11. A pair of insert pieces, compatible with a pair of matching mounting base and end-block couples, each member of said pair of insert pieces according to claim 1, wherein the means to transfer coolant, electrical current and motive force between said pair of matching mounting base and end-block couples are divided between the members of said pair.

12. The pair of insert pieces according to claim 11, wherein the means to provide coolant, to extract coolant and to feed electrical current are comprised in one member of said pair, while the other member comprises means to transfer motive force.

13. The pair of insert pieces according to claim 11, wherein the means to provide coolant, to extract coolant and to transfer motive force are comprised in one member of said pair, while the other member comprises means to feed electrical current.

14. A sputtering module for mounting on a sputter coating installation comprising at least one mounting base and at least one end-block matchable to said mounting base characterised in that said sputtering module further comprises at least one insert piece according to claim 1 between said mounting base and said end-block.

15. A sputtering module wherein two or more insert pieces according to claim 1 between said mounting base and said end-block are inserted, wherein insert pieces are placed in series to one another.

16. A sputtering module for mounting on a sputter coating installation comprising at least one pair of matching mounting base and end-block couples characterised in that said sputtering module further comprises at least one pair of insert pieces according to claim 1 insertable between said matching mounting bases and end-blocks.

17. A method to adapt the distance in a sputter installation between an end-block and its corresponding mounting base by insertion of a piece, said insert piece having interfaces mating with on the end thereof said mounting base and on the other end thereof with said end-block, said insert piece comprising means to operably connect said mounting base to said end-block.
